(19) United States
(12) Patent Application Publication
(10) Pub. No.: US 2025/0247633 A1
(43) Pub. Date: Jul. 31, 2025

(54) IMAGE SENSOR

(71) Applicant: SAMSUNG ELECTRONICS CO., LTD., Suwon-si (KR)

(72) Inventor: Sunghyun NAM, Suwon-si (KR)

(73) Assignee: SAMSUNG ELECTRONICS CO., LTD., Suwon-si (KR)

(21) Appl. No.: 19/025,180

(22) Filed: Jan. 16, 2025

(30) Foreign Application Priority Data
Jan. 25, 2024 (KR) 10-2024-0011725

(51) Int. Cl. H04N 25/10; H04N 25/702; H04N 25/78

(52) U.S. Cl. CPC H04N 25/10; H04N 25/702; H04N 25/78

(57) ABSTRACT

An image sensor includes a first light detection device and a second light detection device being different from each other in at least one of a material and a structure; and a main body configured to generate an image based on electrical signals received from the first light detection device and the second light detection device, and comprising a first groove and a second groove that have different cross-sectional shapes and accommodate the first light detection device and the second light detection device, respectively.

### CROSS-REFERENCE TO RELATED APPLICATION

This application is based on and claims priority to Korean Patent Application No. 10-2024-0011725, filed on Jan. 25, 2024, in the Korean Intellectual Property Office, the disclosure of which is incorporated by reference herein in its entirety.

### BACKGROUND

### 1. Field

One or more example embodiments of the present application relate to an image sensor and an electronic apparatus including the image sensor.

### 2. Description of the Related Art

Image sensors may include an array of multiple pixels that sense red, green, and blue to generate a color image. In addition, color image sensors may include an array of pixels that sense cyan, yellow, green, and magenta instead of pixels that sense red, green, and blue. All of these pixels may be configured to have the same structure for sensing visible light.

Recently, there has been a demand for image sensors that have various functions such as night vision, thermal imaging, and three dimension (3D) imaging. When pixels have different characteristics or include different materials, there is a problem in that it is difficult to fabricate pixels on a single wafer.

### SUMMARY

One or more example embodiments provide an image sensor in which a plurality of light detection devices of different types and functionalities are disposed in one main body and an electronic apparatus including the image sensor.

According to an aspect of the present disclosure, an image sensor may include: a first light detection device and a second light detection device being different from each other in at least one of a material and a structure; and a main body configured to generate an image based on electrical signals received from the first light detection device and the second light detection device, and including a first groove and a second groove that have different cross-sectional shapes and accommodate the first light detection device and the second light detection device, respectively.

The first light detection device has a cross-sectional shape that is incompatible with the second groove, and the second light detection device has a cross-sectional shape that is incompatible with in the first groove.

An area ratio of the second groove to the first groove may be in a range from about 0.8 to about 1.2.

A cross-sectional shape of the first light detection device is same as the cross-sectional shape of the first groove, and a cross-sectional shape of the second light detection device is same as the cross-sectional shape of the second groove.

Each of a cross-sectional shape of the first light detection device and a cross-sectional shape of the second light detection device is one of a circle, an ellipse, and a polygon.

A gap between a lower surface of the first light detection device and a bottom surface of the first groove is less than or equal to a thickness of the first groove.

Circuit layers of the first light detection device and the light detection layers of the first light detection device are sequentially arranged from a bottom surface of the first groove.

A width of an upper surface of the first light detection device is greater than a width of a lower surface of the first light detection device.

An upper surface of the first light detection device extends onto an upper surface of the main body.

A cross-sectional shape of an upper surface of the first light detection device is equal to a cross-sectional shape of an upper surface of the second light detection device.

The image sensor may further include: an electrode pattern configured to electrically connect each of the first light detection device and the second light detection device to the main body. A shape of the electrode pattern connecting the first light detection device to the main body may be different from a shape of the electrode pattern connecting the second light detection device to the main body.

The image sensor may further include: a first electrode, a second electrode, and a third electrode that are spaced apart from each other in the first groove and are configured to electrically connect the first light detection device to the main body.

The first electrode may be configured to apply a ground signal from the main body to the first light detection device. The second electrode may be configured to apply a driving signal from the main body to the first light detection device. The third electrode may be configured to apply the electrical signal from the first light detection device to the main body.

Each of the first light detection device and the second light detection device may include a light detection layer configured to detect light, and a circuit layer configured to output a voltage corresponding to the detected light. The main body may include: a plurality of analog-to-digital converters respectively corresponding to the circuit layers of the first light detection device and the second light detection device, respectively, and configured to convert the voltages received from the corresponding circuit layers into digital signals; and an image processor configured to generate the image by using the digital signals output from the plurality of analog-to-digital converters.

Each of the first light detection device and the second light detection device may include a light detection layer configured to detect light and a first circuit layer configured to output a floating diffusion signal corresponding to the detected light. The main body may include: a plurality of second circuit layers respectively corresponding to the first circuit layers of the first light detection device and the second light detection device, respectively, and configured to output voltages corresponding to the floating diffusion signals received from the corresponding first circuit layers; a plurality of analog-to-digital converters respectively corresponding to the plurality of second circuit layers and configured to convert the voltages received from the corresponding second circuit layers into digital signals; and an image processor configured to generate the image by using the digital signals output from the plurality of analog-to-digital converters.

A material included in the first light detection device may be absent in the second light detection device.

Each of the first light detection device and the second light detection device may include any one of a light detection device based on a group IV semiconductor, a light detection device based on a group III-V semiconductor, a light detection device based on a quantum dot, and a light detection device based on a structure smaller than a wavelength of detected light.

The first light detection device may be configured to detect visible light, and the second light detection device may be configured to detect infrared light or ultraviolet rays.

The main body may include a third light detection device disposed in an upper region of the main body, configured to detect visible light, and output an electrical signal corresponding to light detected by the third light detection device, and thicknesses of the first groove and the second groove may be substantially same as a thickness of the third light detection device.

According to another aspect of the present disclosure, an image sensor may include: a main body including a plurality of grooves with a plurality of different cross-sectional shapes; a plurality of semiconductor chips classified into two or more different chip types based on a material and a structure, wherein among the plurality of semiconductor chips, semiconductor chips of a same chip type have a same cross-sectional shape, and semiconductor chips of different chip types have different cross-sectional shapes, and wherein each of the plurality of grooves is configured to accommodate only a semiconductor chip with a corresponding cross-sectional shape and a corresponding electrode pattern, among the plurality of semiconductor chips with a plurality of different sectional shapes and a plurality of different electrode patterns.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram showing an image sensor according to one or more embodiments;

FIG. 2 is a plan view showing the image sensor of FIG. 1 according to one or more embodiments; FIG. 3 is a cross-sectional view schematically showing the image sensor of FIG. 2;

FIG. 4 is a diagram illustrating in more detail a light detection device included in an image sensor, according to one or more embodiments;

FIG. 5 is a diagram illustrating an image sensor in which a first circuit layer and a plurality of second circuit layers are disposed in a light detection device and a main body, respectively, according to one or more embodiments;

FIG. 6 is a diagram explaining the light detection device of FIG. 5;

FIG. 7 is a diagram showing the second circuit layer included in the main body;

FIG. 8 is a diagram illustrating an image sensor including a plurality of light detection devices with a non-uniform width, according to one or more embodiments;

FIG. 9 is a diagram illustrating an image sensor including light detection devices with different cross-sectional shapes of an upper surface and a lower surface, according to one or more embodiments;

FIG. 10 is a diagram illustrating an image sensor including a first light detection device integrated into a main body, according to one or more embodiments;

FIG. 11 illustrates a process of transferring micro-semiconductor chips through a fluidic self-assembly method in one or more example embodiments of the present disclosure; and

FIG. 12 is a block diagram of an example of an electronic apparatus including an image sensor.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

As used herein, the term “and/or” includes any and all combinations of one or more of the associated listed items. Expressions such as “at least one of,” when preceding a list of elements, modify the entire list of elements and do not modify the individual elements of the list.

The singular forms are intended to include the plural forms as well, unless the context clearly indicates otherwise. Also, when a part “includes” any element, it means that the part may further include other elements, rather than excluding other elements, unless otherwise stated. Sizes or thicknesses of components in the drawings may be arbitrarily exaggerated for convenience of explanation. Further, when a certain material layer is described as being on a substrate or another layer, the material layer may be in contact with the substrate or the other layer, or there may be a third layer between the material layer and the substrate or the other layer. Also, materials constituting each layer are provided merely as an example, and other materials may also be used.

In addition, the terms “ . . . unit”, “module”, etc. described herein mean a unit that processes at least one function or operation, may be implemented as hardware or software, or may be implemented as a combination of hardware and software.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail

Connections of lines or connection members between elements shown in the drawings are illustrative of functional connections and/or physical or circuitry connections, and may be replaced in an actual device, or may be represented as additional various functional connections, physical connections, or circuitry connections.

The term “the” and the similar indicative terms may be used in both the singular and the plural.

The expression such as “at least” used to list elements is intended to limit a list of entire elements, rather than individual elements in the list. For example, expressions such as “at least one of A, B, and C” or “at least one selected from the group consisting of A, B, and C” may be interpreted as only A, only B, only C, or a combination of two or more of A, B, and C, e.g., ABC, AB, BC, and AC

When the terms such as “about” or “substantially” are used in relation to numerical values, the relevant numerical value may be construed as including a manufacturing or operation deviation (e.g., ±10%) of the stated numerical value. In addition, when the expressions such as “generally” and “substantially” are used in relation to a geometric shape, the geometric precision may not be required, and the intention is that the degree of tolerance regarding the shape is within the scope of embodiment. Moreover, regardless of whether a numerical value of a shape is limited by using “about” or “substantially”, such a numerical value or shape should be understood as including a manufacturing or operation deviation (e.g., ±10%) of the stated numerical value

It will be understood that although the terms “first,” “second,” etc. may be used herein to describe various elements, such elements are not limited to the above terms. These terms are only used to distinguish one element from another.

The use of all examples or example terms is merely for describing the technical concept in detail, and the scope thereof is not limited by these examples or example terms unless limited by claims.

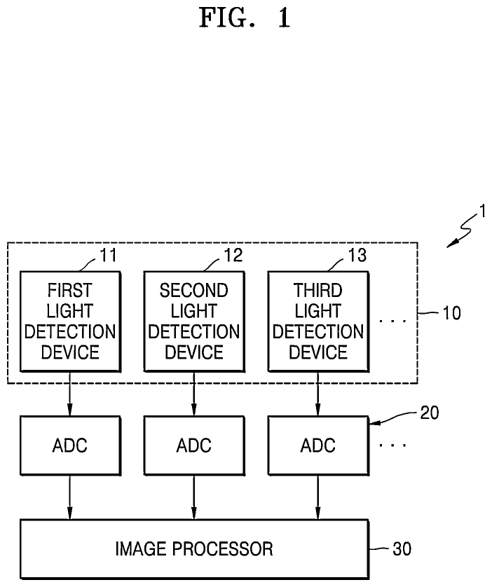

FIG. 1 is a block diagram showing an image sensor 1 according to one or more embodiments. Referring to FIG. 1, the image sensor 1 according to one or more embodiments may include a plurality of light detection devices 10 of different types and/or different functionalities. The plurality of light detection devices 10 may include a first light detection device 11, a second light detection device 12, and a third light detection device 13. Each of the plurality of light detection devices 10 may sense light of a specific wavelength and output the light as an analog signal. Each of the plurality of light detection devices 10 may correspond to one pixel included in an image or may correspond to a plurality of pixels.

The plurality of light detection devices 10 may be of different types due to differences in their materials or structures (e.g., different circuit structures). A material included in one of the plurality of light detection devices 10 may not be included in the other light detection devices 10. According to materials, the plurality of light detection devices 10 may include at least two types of light detection devices among a light detection device based on a group IV semiconductor, a light detection device based on a group III-V semiconductor, and a light detection device based on a quantum dot. A wavelength of detected light may vary depending on the materials of the plurality of light detection devices 10. Alternatively, the plurality of light detection devices 10 may include the light detection device 10 of a structure larger than the wavelength of the detected light and the light detection device 10 of a structure smaller than the wavelength of the detected light. The wavelength of the detected light may vary depending on the sizes, shapes, arrangement, etc. of the structures included in the plurality of light detection devices 10.

The plurality of light detection devices 10 according to one or more embodiments may include at least two types of light detection devices among a light detection device that detects visible light, a light detection device that detects infrared light, and a light detection device that detects ultraviolet rays.

Each of the plurality of light detection devices 10 may output an analog signal corresponding to an intensity of the detected light. The analog signal may include a plurality of signals having different levels (e.g., voltage levels or current levels) depending on the intensity of the detected light.

The image sensor 1 according to one or more embodiments may further include a plurality of analog-to-digital converters 20 that convert analog signals into digital signals. The plurality of analog-to-digital converters 20 may have a one-to-one correspondence with the plurality of light detection devices 10. Each of the plurality of analog-to-digital converters 20 may convert the analog signal generated by each of the plurality of light detection devices 10 into a digital signal. The digital signal may include a plurality of digital values converted from levels of the plurality of signals of the analog signal.

The image sensor 1 according to one or more embodiments may further include an image processor 30 that generates an image by using the digital signal. The image processor 30 may receive the digital signal from each of the plurality of analog-to-digital converters 20.

The image processor 30 may generate an image by performing calibration to remove noise and/or distortion from the digital signal. For example, the image processor 30 may perform noise reduction processing, gain adjustment, waveform normalization processing, interpolation processing, white balance processing, gamma processing, edge emphasis processing, binning, etc. Some functions of the image processor 30 may be performed by external devices.

The image processor 30 may generate separate images for each type of the plurality of light detection devices 10, and may also generate an integrated image based on signals output from the plurality of light detection devices 10 of different types. The plurality of light detection devices 10 may include different types of heterogeneous sensors, such as a combination of silicon photodiode pixels and InGaAs photodiode pixels, or a combination of silicon photodiode pixels and quantum dot photodiode pixels. Alternatively, the plurality of light detection devices 10 may include a combination of a sensor element and a non-sensor element, such as a photodetector and a light emitting diode (LED), or a photodetector and a laser diode (LD).

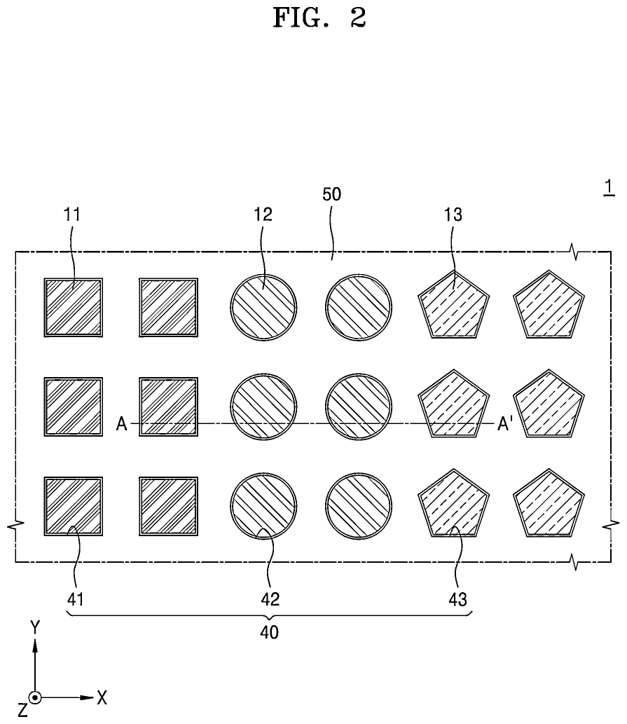

FIG. 2 is a plan view showing the image sensor 1 of FIG. 1 according to one or more embodiments. FIG. 3 is a cross-sectional view schematically showing the image sensor 1 of FIG. 2.

Referring to FIGS. 2 and 3, the image sensor 1 may include a body 50 including a plurality of grooves 40 with different cross-sectional shapes on an upper surface thereof. A specific light detection device among the plurality of light detection devices 10 may be disposed on each of the plurality of grooves 40.

The main body 50 may include, for example, an organic material such as silicon, glass, sapphire, polymer, an inorganic material, a conductive material, etc. The main body 50 may include a transistor, a capacitor, an electrode pattern, etc. that drive the light detection device 10, and the plurality of analog-to-digital converters 20 and the image processor 30 described with reference to FIG. 1 may be disposed in the main body 50. For example, the main body 40 may be a readout integrated circuit (ROIC) substrate that includes a readout circuit, memory, or logic circuit. The main body 40 may have individual electrodes E1-E3 exposed on its surface to allow connection with each of the plurality of light detection devices 10 through a self-assembly method.

The plurality of grooves 40 having different cross-sectional shapes may be disposed on an upper surface of the main body 50. The plurality of grooves 40 may each be pillar-shaped. The plurality of grooves 40 may serve to guide an assembly of the light detection device 10 when the light detection device 10 is assembled to the main body 50. The plurality of grooves 40 may be manufactured by patterning, etching, or molding using a photolithography process, but are not limited thereto.

Each of the plurality of grooves 40 may have a shape that may accommodate a specific type of light detection device 10, but may not accommodate the remaining light detection devices 10. The plurality of grooves 40 may each have cross-sectional shapes that are the same as or similar to that of the specific type of light detection device 10 that may be accommodated. The plurality of grooves 40 may each have a width greater than a width of the specific type of light detection device 10 that may be accommodated. Each of the plurality of grooves 40 may have a cross-sectional area or cross-sectional shape that may not accommodate types of light detection devices 10 other than the specific type of light detection device 10. For example, the main body 50 may include a first groove 41 having a rectangular cross-sectional shape, a second groove 42 having a circular cross-sectional shape, and a third groove 43 having a pentagonal cross-sectional shape. The cross-sectional shapes of the plurality of grooves 40 may be various, such as triangular or hexagonal.

An area ratio of the remaining grooves 40 to any one of the plurality of grooves 40 may be in a range from about 0.8 to about 1.2.

Each of the plurality of grooves 40 may have a thickness such that at least a part of the light detection device 10 accommodated therein is disposed in the groove 40. For example, approximately ½ of the area of the light detection device 10 may be disposed in each of the plurality of grooves 40. However, the disclosure is not limited thereto. The entire light detection device 10 may be disposed in each of the plurality of grooves 40.

The plurality of light detection devices 10 of different types may have different cross-sectional shapes. Each of the plurality of light detection devices 10 may have a pillar shape. The cross-sectional shape of each of the plurality of light detection devices 10 may be accommodated in one of the plurality of grooves 40 included in the main body 50, but may not be accommodated in the remaining grooves 40, which will be described below. For example, a first light detection device 11 may have a rectangular cross-sectional shape, a second photodetector 12 may have a circular cross-section, and a third photodetector 13 may have a pentagonal cross-section. In addition, the plurality of light detection devices 10 may have various cross-sectional shapes.

The plurality of light detection devices 10 according to one or more embodiments may have different cross-sectional shapes for each type. The cross-sectional shape of each of the plurality of light detection devices 10 may be accommodated in one of the plurality of grooves 40 included in the main body 50 but may not accommodated in the remaining grooves 40. For example, the first light detection device 11 may have a rectangular cross-sectional shape, the second photodetector 12 may have a circular cross-sectional shape, and the third photodetector 13 may have a pentagonal cross-sectional shape. An area ratio of the remaining light detection devices 10 to any one of the plurality of light detection devices 10 may be about 0.8 or more and about 1.2 or less. Thus, the first light detection device 11 may be disposed in the first groove 41 but may not be disposed in the second groove 42 and the third groove 43, and the second light detection device 12 may be disposed in the second groove 42 but may not be disposed in the first groove 41 and the third groove 43. In addition, the third light detection device 13 may be disposed in the third groove 43, but may not be disposed in the first groove 41 and the second groove 42. The plurality of light detection devices 10 may be transferred to the main body 50 by using a fluidic self-assembly method or a pick and place method.

It may be difficult to manufacture the plurality of light detection devices 10 of different types on a single wafer due to differences in manufacturing methods. Accordingly, the plurality of light detection devices 10 of different types may be manufactured individually using different manufacturing processes. When assembling the plurality of light detection devices 10 manufactured individually into one main body 50, the plurality of light detection devices 10 may have different cross-sectional shapes and be disposed in the corresponding grooves 40. This process may facilitate the easy manufacturing of the image sensor 1.

In particular, the plurality of grooves 40 with different cross-sectional shapes may be disposed on the upper surface of the main body 50, and each of the plurality of light detection devices 10 may have a cross section that is accommodated only in the corresponding groove 40 among the plurality of grooves 40 and is not accommodated in the remaining grooves 40, and thus, the light detection device 10 may be stably coupled to the main body 50 without an error.

The plurality of light detection devices 10 of different types may be manufactured separately, but regardless of types of the plurality of light detection devices 10, the analog-to-digital converter 20 and the image processor 30 applied to image generation may be manufactured in one main body 50, and thus, the compact image sensor 1 may be implemented.

An electrode pattern E capable of exchanging electrical signals between the light detection device 10 and the main body 50 may be further disposed in each of the plurality of grooves 40. The electrode pattern E may differ depending on types of the first light detection device 11, the second light detection device 12, and the third light detection device 13. The different number of electrodes for each light detection device in FIG. 3 means a different electrode pattern for each type of light detection device. For example, a plurality of electrodes connecting the first light detection device 11 with the main body 50 may have a bar shape spaced apart in a first direction (e.g., X direction) and extending in a second direction (e.g., Y direction), and a plurality of electrodes connecting the second light detection device 12 with the main body 50 may have an annular shape with the same center. In addition, a plurality of electrodes connecting the third light detection device 13 with the main body 50 may have a bar shape spaced apart in the second direction (e.g., Y direction) and extending in the first direction (e.g., X direction).

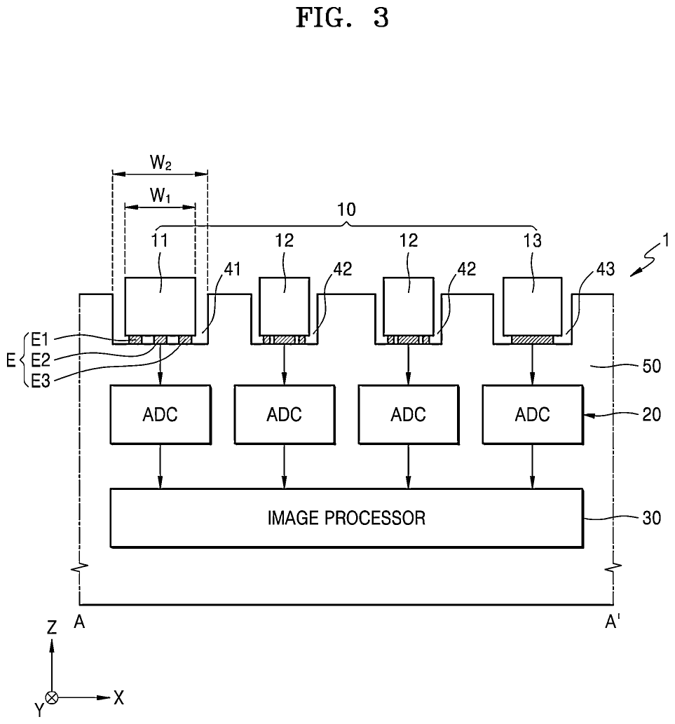

The electrode pattern E may include three or more electrodes spaced apart from each other. For example, the electrode pattern E may include a first electrode E1 that applies a ground signal from the main body 50 to the light detection device 10, a second electrode E2 that applies a driving voltage from the main body 50 to the light detection device 10, and a third electrode E3 that provides an electrical signal corresponding to light detected from the light detection device 10 to the main body 50. The first electrode E1, the second electrode E2, and the third electrode E3 may be spaced apart from each other in the groove 40. Thicknesses of the first electrode E1, the second electrode E2, and the third electrode E3 may be less than a thickness of the groove 40. FIG. 4 is a diagram illustrating in more detail the light detection device 10 included in the image sensor 1 according to one or more embodiments.

Referring to FIG. 4, the light detection device 10 may include a light detection layer 210 that detects light of a specific wavelength. The light detection layer 210 may have a different material or structure according to a type of light detection device 10. For example, the light detection layer 210 may include a group IV semiconductor material, a group III-V semiconductor material, or quantum dots. The first light detection device 11 may be a light detection device based on a group IV semiconductor, the second light detection device 12 may be a light detection device based on a group III-V semiconductor, and the third light detection device 13 may be a light detection device based on a quantum dot. Alternatively, a light detection layer of the first light detection device 11 may be configured as a structure smaller than a wavelength of detected light, and a light detection layer of each of the second light detection device 12 and the third light detection device 13 may be configured as a structure larger than the wavelength of the detected light.

The light detection device 10 may further include a circuit layer 220 disposed on a lower surface of the light detection layer 210 and converting the light detected by the light detection layer 210 into an electrical signal. When the light detection device 10 is disposed in the groove 40, the circuit layer 220 and the light detection layer 210 may be sequentially arranged from a bottom surface of the groove 40. The circuit layer 220 may include one or more transistors.

As shown in FIG. 4, the light detection device 10 may include a photodiode PD, a transfer transistor TX or a transfer gate TG, a floating diffusion node FD, a conversion gain transistor DCG, a reset transistor RX, a source follower transistor SF, and a selection transistor SEL.

The photodiode PD may be included in the light detection layer 210, and the transfer transistor TX, the floating diffusion node FD, the conversion gain transistor DCG, the reset transistor RX, the source follower transistor SF, and the selection transistor SEL may be included in the circuit layer 220. In addition to the photodiode PD, the light detection layer 210 may further include a filter layer that filters light of a specific wavelength, or a band filter that resonates light of a specific wavelength. A type of the light detection device 10 may be determined according to materials or structures of the filter layer and the band filter, but for convenience of explanation, only the photodiode PD is shown and is not limited thereto.

The photodiode PD included in the light detection layer 210 may generate charges in proportion to the amount of incident light. The photodiode PD may generate electrons with a negative charge and holes with a positive charge in response to incident light. The photodiode PD may receive a ground signal from the main body 50 through the first electrode E1. A plurality of photodiodes PD may be provided. The plurality of photodiodes PD may share one floating diffusion node FD, reset transistor RX, conversion gain transistor DCG, source follower transistor SF, and selection transistor SEL.

The transfer gate TG may be disposed between the photodiode PD and the floating diffusion node FD and may transmit charges generated in the photodiode PD to the floating diffusion node FD. The transfer transistor TX may include the transfer gate TG, a drain connected to and the photodiode PD, and a source connected to the floating diffusion node FD.

The conversion gain transistor DCG may include a conversion gain gate, a source connected to the drain of the reset transistor RX, and a drain connected to the floating diffusion node FD.

The conversion gain transistor DCG may change capacitance of the floating diffusion node FD according to a conversion gain signal. When the conversion gain transistor DCG is turned on, the capacitance increases, and thus, the circuit layer 220 may operate in a low conversion gain mode. Conversely, when the conversion gain transistor DCG is turned off, the capacitance decreases, and thus, the circuit layer 220 may operate with a high conversion gain.

The reset transistor RX may include a reset gate, a source connected to a driving voltage VD, and a drain connected to the source of the conversion gain transistor DCG. When the reset transistor RX is turned on according to the reset control signal and the conversion gain transistor DCG is turned on according to the conversion gain signal, the floating diffusion node FD may be reset based on a driving voltage Vpix. Specifically, charges accumulated in the floating diffusion node FD may be discharged so that the floating diffusion node FD may be reset. At this time, a reset signal corresponding to a voltage level of the floating diffusion node FD may be output. The driving voltage VD may be applied from the main body 50 through a second electrode E2.

The gate of the source follower transistor SF may be electrically connected to the floating diffusion node FD. The source of the source follower transistor SF may be electrically connected to the source of the selection transistor SEL. The drain of the source follower transistor SF may be electrically connected to the driving voltage VD.

A potential of the floating diffusion node FD may change according to the amount of charges accumulated in the floating diffusion node FD, and the source follower transistor SF may amplify a change in the potential of the floating diffusion node FD and output the amplified potential change to the source of the source follower transistor SF.

The source of the selection transistor SEL may be electrically connected to a selection gate and the source of the source follower transistor SF. The drain of the selection transistor SEL may be electrically connected to an output voltage line. The output voltage line may be electrically connected to the third electrode E3 and provide an output voltage Vout to the main body 50.

The light detection device 10 includes the circuit layer 220, thereby more efficiently converting the charges generated in the light detection layer 210 into an electrical signal. In FIG. 4, the light detection device 10 may output the output voltage Vout, which is an analog signal, but the disclosure is not limited thereto. Some components of the circuit layer 220 may be disposed in the light detection device 10, and other components may be disposed in the main body 50.

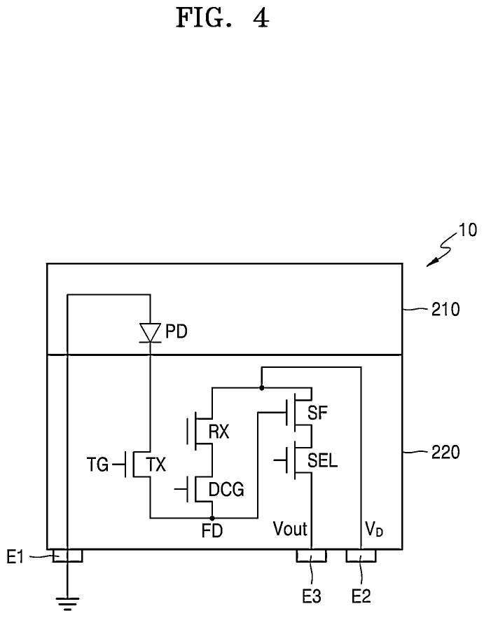

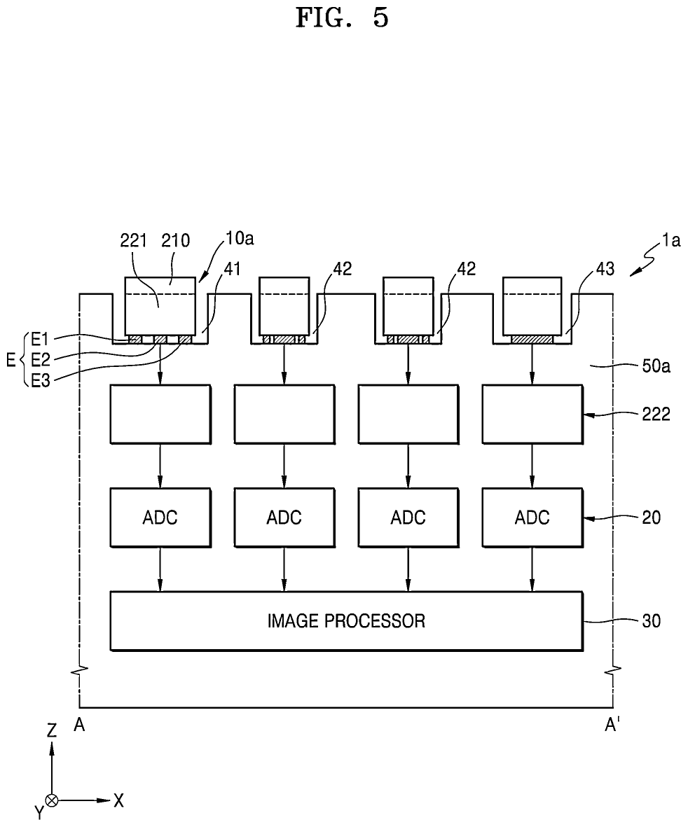

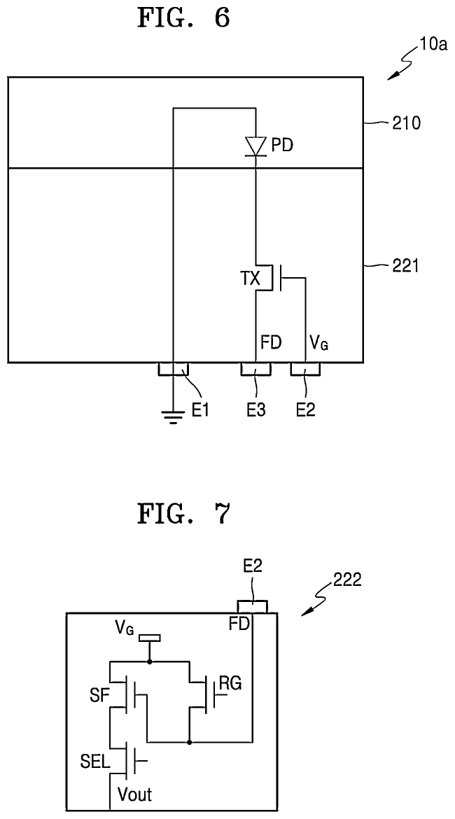

FIG. 5 is a diagram illustrating an image sensor 1a in which a first circuit layer 221 and a plurality of second circuit layers 222 are disposed in a light detection device 10a and the main body 50, respectively, according to one or more embodiments. FIG. 6 is a diagram explaining the light detection device 10a of FIG. 5. FIG. 7 is a diagram showing the second circuit layer 222 included in the main body 50.

Referring to FIGS. 5 and 6, the light detection device 10a may include the light detection layer 210 including a photodiode and the first circuit layer 221 including one or more transistors. The first circuit layer 221 may include the transfer transistor TX. The transfer transistor TX may include the transfer gate TG, a drain connected to the photodiode PD, and a source connected to the floating diffusion node FD.

The first circuit layer 221 may receive a ground signal of the photodiode from the main body 50 through the first electrode E1 and a transfer gate signal from the main body 50 through the second electrode E2, and provide a floating diffusion signal, which is the amount of charges, to the main body 50 through the third electrode E3. The transfer gate signal may be a driving signal of the first circuit layer 221. The first circuit layer 221 may be disposed on a lower surface of the light detection layer 210.

Referring to FIGS. 5 and 7, the main body 50 may further include a plurality of second circuit layers 222 respectively corresponding to the plurality of light detection devices 10. The second circuit layer 222 may be disposed between the light detection device 10 and the analog-to-digital converter 20.

The second circuit layer 222 may amplify the floating diffusion signal received from the first circuit layer 221 and output a voltage corresponding to detected light. The second circuit layer 222 may include the conversion gain transistor DCG, the reset transistor RX, the source follower transistor SF, and the selection transistor SEL. The conversion gain transistor DCG, the reset transistor RX, the source follower transistor SF, and the selection transistor SEL have been described previously, and thus, detailed descriptions thereof will be omitted.

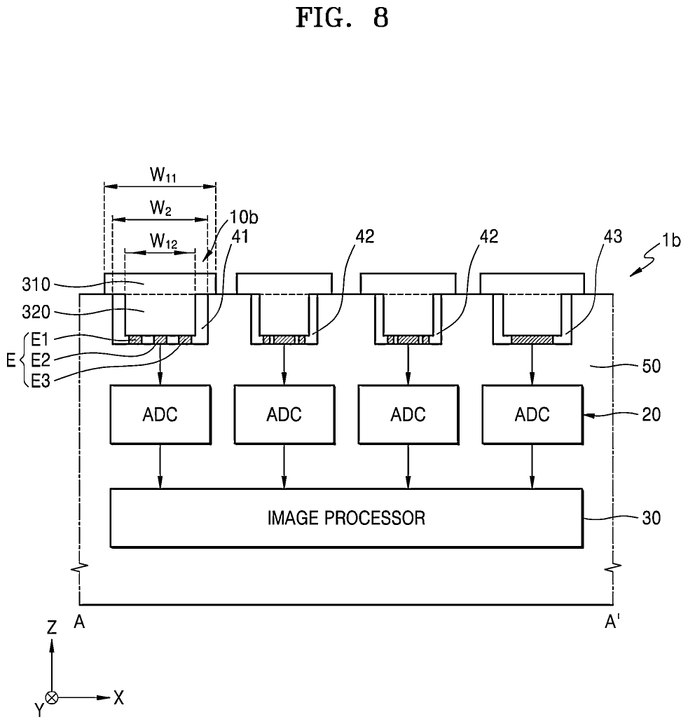

FIG. 8 is a diagram illustrating an image sensor 1b including a plurality of light detection devices 10b with a non-uniform width, according to one or more embodiments.

Referring to FIG. 8, a width of at least one of the plurality of light detection devices 10b may not be uniform. For example, the light detection device 10 may include a first region 310 having a first width W₁₁ and a second region 320 having a second width W₁₂ that is less than the first width W₁₁. The first region 310 may be the light detection layer 210, and the second region 320 may be the circuit layer 220.

The first width W₁₁ of the first region 310 may be greater than a width W₂ of the corresponding groove 40, and the second width W₁₂ of the second region 320 may be less than the width W₂ of the corresponding groove 40. The second region 320 may be disposed in the groove 40, and the first region 310 may extend and be disposed on an upper surface of the main body 50.

Because the first width W₁₁ of the first region 310 is larger than the width W₂ of the groove 40, even though the image sensor 1 moves due to an external impact, etc., the possibility of the light detection device 10 being separated to the outside may be reduced. In addition, the light detection layer 210 may be more widely disposed on an upper surface of the image sensor 1, and thus, the light detection layer 210 may detect light in a wider region and increase light detection efficiency.

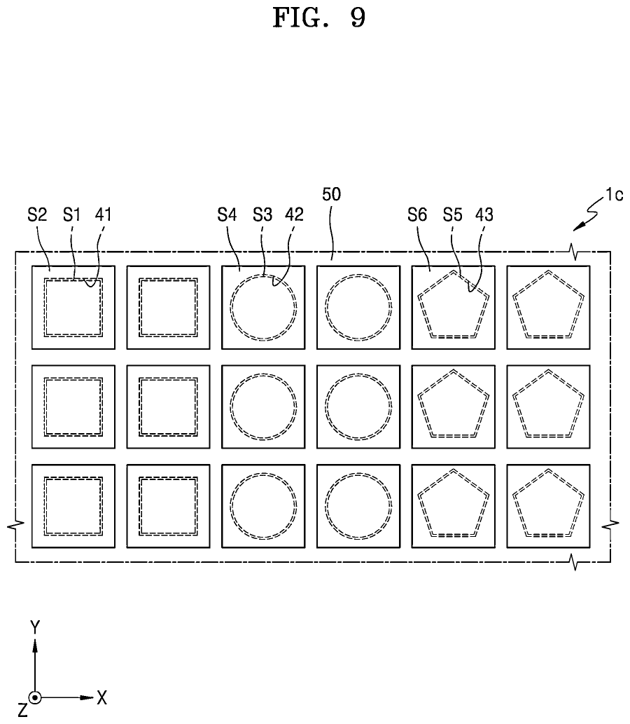

FIG. 9 is a diagram illustrating an image sensor including a first light detection device 11a, a second light detection device 11b, and a third light detection device 11c with different cross-sectional shapes of an upper surface and a lower surface, according to one or more embodiments.

Referring to FIG. 9, cross-sectional shapes of lower surfaces S₁, S₃, and S₅ of different types of the first light detection device 11b, the second light detection device 12b, and the third light detection device 13b may respectively correspond to cross-sectional shapes of a first grove 41, a second groove 42, and a third groove 43 in which the first light detection device 11b, the second light detection device 12b, and the third light detection device 13b are respectively accommodated, and cross-sectional shapes of upper surfaces S₂, S₄, and S₆ of the first light detection device 11b, the second light detection device 12b, and the third light detection device 13b may be different from the cross-sectional shapes of the first grove 41, the second groove 42, and the third groove 43. For example, the cross-sectional shape of the lower surface S₁ of the first light detection device 11a may be rectangular to correspond to the first groove 41, and the cross-sectional shape of the lower surface S₃ of the second light detection device 12b may be circular to correspond to the second groove 42. Also, the cross-sectional shape of the lower surface S₅ of the third light detection device 13b may be pentagonal to correspond to the third groove 43. However, the cross-sectional shapes of the upper surfaces S₂, S₄, and S₆ of the first light detection device 11b, the second light detection device 12b, and the third light detection device 13b may all be rectangular. The cross-sectional shapes of lower surfaces S₁, S₃, and S₅ of the first light detection device 11b, the second light detection device 12b, and the third light detection device 13b may be used to be accommodated in the grooves 40, and the cross-sectional shapes of the upper surfaces S₂, S₄, and S₆ of the first light detection device 11b, the second light detection device 12b, and the third light detection device 13b are used to detect a larger amount of light, and thus, the light detection device 10 may be stably accommodated in the groove 40 and light detection efficiency may be increased.

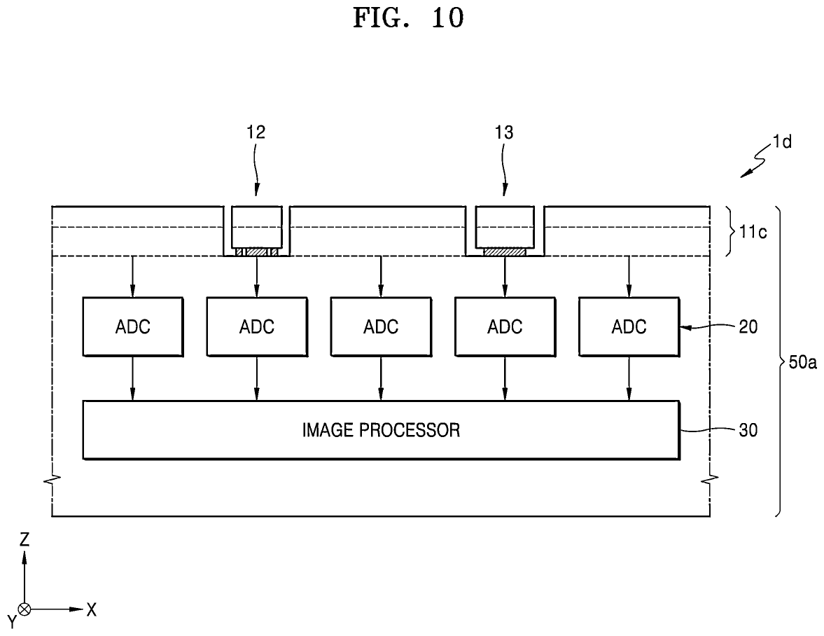

FIG. 10 is a diagram illustrating an image sensor 1d including a first light detection device 11c integrated into a main body according to one or more embodiments. When an image sensor includes a plurality of light detection devices of different types, a specific type of light detection device may include more light detection devices of different types. A large number of types of light detection devices may be manufactured integrally with a main body, and a small number of types of light detection devices may be manufactured in an assembled manner.

For example, when the image sensor 1d includes a plurality of first light detection devices 11c that detect visible light, the second light detection device 12 that detects infrared light, and the third light detection device 13 that detects ultraviolet rays, the first light detection device 11c may be formed integrally with a main body 50a. The second groove 42 and the third groove 43 may be generated by forming the first light detection device 11c. For example, the first light detection device 11c may not be disposed in the second groove 42 and the third groove 43 in an upper surface of the main body 50a. The image sensor 1d may include the second groove 42 and the third groove 43 to accommodate the second light detection device 12 and the third light detection device 13. The second light detection device 12 may be accommodated in the second groove 42, and the third light detection device 13 may be accommodated in the third groove 43.

The plurality of light detection devices 11c are formed integrally with the main body 50a, and thus, a transfer process on the light detection devices may be reduced.

In one or more embodiments of the disclosure, the plurality of light detection devices 10, 10a, 10b, and 10c may be transferred to the main body 50 and 50a using a fluidic self-assembly method.

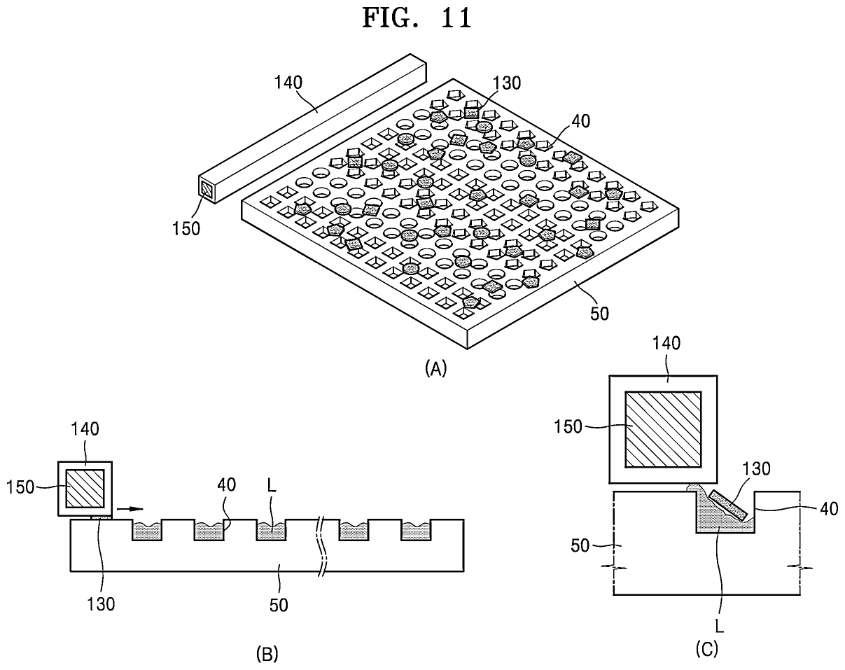

FIG. 11 illustrates a process of transferring micro-semiconductor chips through a fluidic self-assembly method in one or more example embodiments of the present disclosure.

As shown in (A) of FIG. 11, the main body 50, including the plurality of grooves 40, may be prepared. The grooves 40 may be configured with different cross-sectional shapes and sizes to arrange or accommodate correspondingly shaped and sized micro-semiconductor chips 130, such as the light detection devices 10, 10a, 10b, and 10c. For example, grooves 40 with a circular cross-section may accommodate only micro-semiconductor chips 130 with a circular cross-section, while grooves 40 with a rectangular cross-section may accommodate only micro-semiconductor chips 130 with a rectangular cross-section. The micro-semiconductor chip 130 may include various types of semiconductor chips of micro sizes, with dimensions equal to or less than 1000 μm or 200 μm. Examples of such chips include light-emitting diodes (LEDs), complementary metal-oxide semiconductors (CMOS), CMOS image sensors (CIS), vertical-cavity surface-emitting lasers (VCSELs), photodiodes (PDs), and memory devices

A liquid may be supplied to the main body 50, filling the grooves 40. Examples of suitable liquids include water, ethanol, alcohol, polyol, ketone, halocarbon, acetone, flux, and organic solvents like isopropyl alcohol (IPA). However, the type of liquid is not limited to these examples. Various methods can be used to supply the liquid to the grooves 40, including spraying, dispensing, inkjet dot spreading, or spilling the liquid onto the main body 50.

The plurality of micro-semiconductor chips 130 may then be supplied to the main body 50. These chips can be directly sprinkled over the transfer substrate 120 without any additional liquids or included in a suspension. Methods of supplying the chips in a suspension include spraying, dispensing, inkjet dot spreading, or spilling the suspension onto the main body 50.

As shown in (B) of FIG. 11, an absorber 140 capable of absorbing liquid may be used to scan the main body 50. The absorber 140 can be made from any material capable of absorbing liquid, such as fabric, tissue, polyester fiber, paper, or a wiper. The absorber 140 may be used alone or coupled to a supporting plate 150 for convenience. The supporting plate 150 may have various shapes and structures suitable for scanning, including a rod, blade, plate, or wiper. The absorber 140 may be attached to or surround the supporting plate 150.

The absorber 140 may scan the main body 50 by applying appropriate pressure and maintaining contact with it, absorbing the liquid as it moves. This scanning may involve various movements, such as sliding, rotating, translating, reciprocating, rolling, spinning, or rubbing. The scanning may be performed by moving either the main body 50 or the absorber 140 while maintaining the position of the other, or by moving both in collaboration.

After scanning, any micro-semiconductor chips that did not enter the grooves 40 and remain on the main body 50, referred to as dummy chips, may be removed. The transfer process continues until all the grooves 40, or a predetermined number or percentage of them, are filled with the micro-semiconductor chips 130. This method allows for the rapid transfer of the micro-semiconductor chips 130 onto the main body 50.

Image (C) of FIG. 11 shows an enlarged view of one of the grooves 40. During the scanning process, the micro-semiconductor chip 130 is positioned between the absorber 140 and the main body 50. As the absorber 140 absorbs the liquid L from the grooves 40, the micro-semiconductor chip 130 falls into the grooves 40.

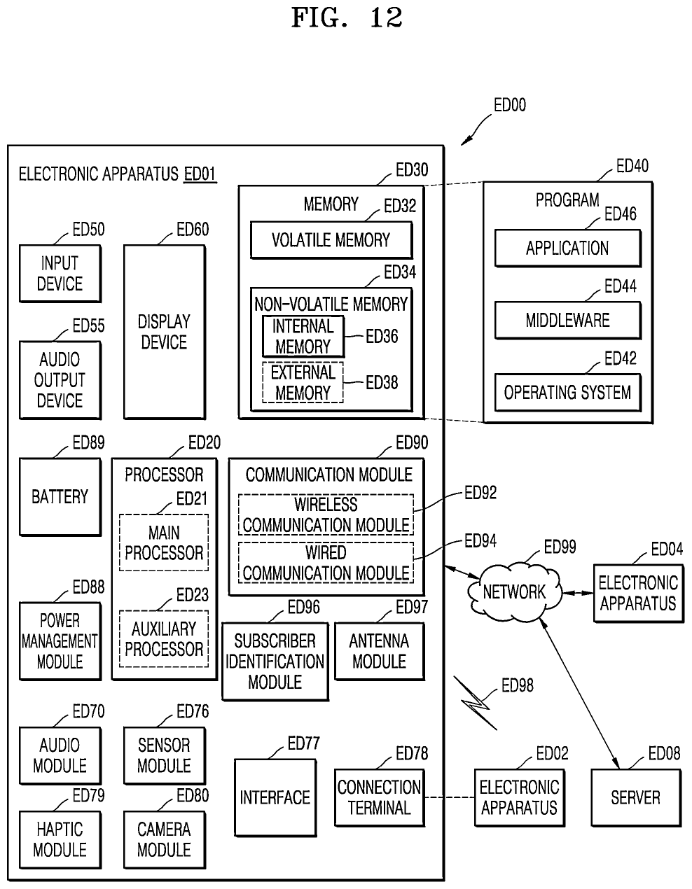

FIG. 12 is a block diagram of an example of an electronic apparatus ED01 including an image sensor. Referring to FIG. 12, in a network environment ED00, an electronic apparatus ED01 may communicate with another electronic apparatus ED02 through a first network ED98 (a short-range wireless communication network, etc.) or may communicate with another electronic apparatus ED04 and/or a server ED08 through a second network ED99 (a remote wireless communication network, etc.) The electronic apparatus ED01 may communicate with the electronic apparatus ED04 through the server ED08. The electronic apparatus ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some of these components (e.g., the display device ED60) may be omitted or other components may be added. Some of these components may be implemented as one integrated circuit. For example, the sensor module ED76 (a fingerprint sensor, an iris sensor, an illuminance sensor, etc.) may be implemented by being embedded in the display device ED60 (a display, etc.)

The processor ED20 may control one or a plurality of other components (hardware, software components, etc.) of the electronic apparatus ED01 connected to the processor ED20 by executing software (e.g., a program ED40), and may perform various data processing or operations. As a part of data processing or computations, the processor ED20 may load commands and/or data received from other components (the sensor module ED76 and the communication module ED90, etc.) into a volatile memory ED32 and may process commands and/or data stored in the volatile memory ED32, and the resulting data may be stored in a non-volatile memory ED34. The processor ED20 may include a main processor ED21 (a central processing unit, an application processor, etc.) and an auxiliary processor ED23 (a graphics processing unit, an image signal processor, a sensor hub processor, a communication processor, etc.) that may be operated independently or together with the main processor ED21. The auxiliary processor ED23 may use less power than the main processor ED21 and may perform a specialized function.

The auxiliary processor ED23 is configured to replace the main processor ED21 while the main processor ED21 is in the inactive state (sleep state) or the main processor ED21 while the main processor ED21 is in the active state (the application execution state). Together with the processor ED21, functions and/or states related to some of the components of the electronic apparatus ED01 (the display device ED60, the sensor module ED76, the communication module ED90, etc.) may be controlled. The auxiliary processor ED23 (an image signal processor, a communication processor, etc.) may be implemented as a part of other functionally related components (the camera module ED80, the communication module ED90, etc.)

The memory ED30 may store various pieces of data required by components of the electronic apparatus ED01 (such as the processor ED20 and the sensor module ED76). The data may include, for example, input data and/or output data for software (such as the program ED40) and instructions related thereto. The memory ED30 may include the volatile memory ED32 and/or the nonvolatile memory ED34.

The program ED40 may be stored as software in the memory ED30 and may include an operating system ED42, middleware ED44, and/or an application ED46.

The input device ED50 may receive a command and/or data to be used in a component (such as, the processor ED20) of the electronic apparatus ED01 from the outside of the electronic apparatus ED01 (e.g., a user). The input device ED50 may include a microphone, a mouse, a keyboard, and/or a digital pen (such as, a stylus pen).

The audio output device ED55 may output a sound signal to the outside of the electronic apparatus ED01. The audio output device ED55 may include a speaker and/or a receiver. The speaker may be used for general purposes, such as, multimedia playback or recording playback, and the receiver may be used to receive an incoming call. The receiver may be incorporated as a part of the speaker or may be implemented as an independent separate device.

The display device ED60 may visually provide information to the outside of the electronic apparatus ED01. The display device ED60 may include a control circuit for controlling a display, a hologram device, or a projector, and a corresponding device. The display device ED60 may include touch circuitry configured to sense a touch, and/or sensor circuitry configured to measure the intensity of force generated by the touch (a pressure sensor, etc.)

The audio module ED70 may convert sound into an electric signal or, conversely, convert an electric signal into sound. The audio module ED70 may obtain sound through the input device ED50 or output sound through a speaker and/or headphones of the audio output device ED55 and/or another electronic apparatus (the electronic apparatus ED02, etc.) directly or wirelessly connected to the electronic apparatus ED01

The sensor module ED76 may detect an operating state (power, temperature, etc.) of the electronic apparatus ED01 or an external environmental state (a user state, etc.), and generate an electrical signal and/or data value corresponding to the sensed state. The sensor module ED76 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or more designated protocols that may be used by the electronic apparatus ED01 to directly or wirelessly connect with another electronic apparatus (the electronic apparatus ED02, etc.) The interface ED77 may include a High Definition Multimedia Interface (HDMI), a Universal Serial Bus (USB) interface, an SD card interface, and/or an audio interface.

A connection terminal ED78 may include a connector through which the electronic apparatus ED01 may be physically connected to another electronic apparatus (the electronic apparatus ED02, etc.) The connection terminal ED78 may include an HDMI connector, a USB connector, an SD card connector, and/or an audio connector (a headphones connector, etc.)

The haptic module ED79 may convert an electrical signal into a mechanical stimulus (vibration, movement, etc.) or an electrical stimulus that may be perceived by the user through tactile or kinesthetic sense. The haptic module ED79 may include a motor, a piezoelectric element, and/or an electrical stimulation device.

The camera module ED80 may capture still images and moving images. The camera module ED80 may include a lens assembly including one or more lenses, the image sensor described above, image signal processors, and/or flashes. The lens assembly included in the camera module ED80 may collect light emitted from an object, an image of which is to be captured.

The power management module ED88 may manage power supplied to the electronic apparatus ED01. The power management module ED88 may be implemented as part of a Power Management Integrated Circuit (PMIC).

The battery ED89 may supply power to components of the electronic apparatus ED01. The battery ED89 may include a non-rechargeable primary cell, a rechargeable secondary cell, and/or a fuel cell.

The communication module ED90 may support the establishment of a direct (wired) communication channel and/or a wireless communication channel between the electronic apparatus ED01 and other electronic apparatuses (the electronic apparatus ED02, the electronic apparatus ED04, the server ED08, etc.) and perform communications through the established communication channel. The communication module ED90 may include one or a plurality of communication processors that operate independently from the processor ED20 (an application processor, etc.) and support direct communication and/or wireless communication. The communication module ED90 may include a wireless communication module ED92 (a cellular communication module, a short-range wireless communication module, and a Global Navigation Satellite System (GNSS) communication module, etc.) and/or a wired communication module ED94 (a Local Area Network (LAN) communication module, a power line communication module, etc.) Among these communication modules, a corresponding communication module may communicate with other electronic apparatuses through the first network ED98 (a short-range communication network, such as Bluetooth, WiFi Direct, or Infrared Data Association (IrDA)) or the second network ED99 (a telecommunication network, such as a cellular network, the Internet, or a computer network, such as a LAN, a wide area network (WAN), etc.) The various types of communication modules may be integrated into one component (a single chip, etc.) or implemented as a plurality of components (plural chips) separate from each other. The wireless communication module ED92 may identify and authenticate the electronic apparatus ED01 within a communication network, such as the first network ED98 and/or the second network ED99, by using subscriber information (such as, an International Mobile Subscriber Identifier (IMSI)) stored in a subscriber identification module ED96.

The antenna module ED97 may transmit or receive signals and/or power to and from the outside (other electronic apparatuses, etc.) An antenna may include a radiator having a conductive pattern formed on a substrate (a printed circuit board (PCB), etc.) The antenna module ED97 may include one or a plurality of antennas. When a plurality of antennas are included in the antenna module ED97, an antenna suitable for a communication method used in a communication network, such as the first network ED98 and/or the second network ED99, from among the plurality of antennas may be selected by the communication module ED90. Signals and/or power may be transmitted or received between the communication module ED90 and another electronic apparatus through the selected antenna. In addition to the antenna, other components (a radio-frequency integrated circuit (RFIC), etc.) may be included as part of the antenna module ED97.

Some of the components, between peripheral devices, may be connected to each other through communication methods (a bus, General Purpose Input and Output (GPIO), Serial Peripheral Interface (SPI), Mobile Industry Processor Interface (MIPI), etc.) and signals (commands, data, etc.) may be interchangeable.

Commands or data may be transmitted or received between the electronic apparatus ED01 and an external electronic apparatus (the electronic apparatus ED04) through the server ED08 connected to the second network ED99. The electronic apparatuses ED02 and ED04 may be the same type as or different types from the electronic apparatus ED01. All or part of the operations executed by the electronic apparatus ED01 may be executed by one or more of the electronic apparatuses ED02 and ED04 and the server ED08. For example, when the electronic apparatus ED01 needs to perform a function or service, the electronic apparatus ED01 may request one or more other electronic apparatuses to perform part or all of the function or service instead of executing the function or service itself. One or more other electronic apparatuses receiving the request may execute an additional function or service related to the request, and transmit a result of the execution to the electronic apparatus ED01. To this end, cloud computing, distributed computing, and/or client-server computing technologies may be used.

The image sensor according to one or more embodiments includes a plurality of grooves having different cross-sectional shapes and accommodates a plurality of light detection devices having the same cross-sectional shape, thereby facilitating coupling of the light detection devices and the main body.

One image processor processes electrical signals output from a plurality of light detection devices of different types, and thus, a compact image sensor may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a first light detection device and a second light detection device being different from each other in at least one of a material and a structure; and
a main body configured to generate an image based on electrical signals received from the first light detection device and the second light detection device, and comprising a first groove and a second groove that have different cross-sectional shapes and accommodate the first light detection device and the second light detection device, respectively.

2. The image sensor of claim 1, wherein
the first light detection device has a cross-sectional shape that is incompatible with the second groove, and
the second light detection device has a cross-sectional shape that is incompatible with in the first groove.

3. The image sensor of claim 1, wherein an area ratio of the second groove to the first groove is in a range from about 0.8 to about 1.2.

4. The image sensor of claim 1, wherein
a cross-sectional shape of the first light detection device is same as the cross-sectional shape of the first groove, and
a cross-sectional shape of the second light detection device is same as the cross-sectional shape of the second groove.

5. The image sensor of claim 4, wherein each of a cross-sectional shape of the first light detection device and a cross-sectional shape of the second light detection device is one of a circle, an ellipse, and a polygon.

6. The image sensor of claim 1, wherein a gap between a lower surface of the first light detection device and a bottom surface of the first groove is less than or equal to a thickness of the first groove.

7. The image sensor of claim 1, wherein circuit layers of the first light detection device and the light detection layers of the first light detection device are sequentially arranged from a bottom surface of the first groove.

8. The image sensor of claim 1, wherein a width of an upper surface of the first light detection device is greater than a width of a lower surface of the first light detection device.

9. The image sensor of claim 7, wherein an upper surface of the first light detection device extends onto an upper surface of the main body.

10. The image sensor of claim 1, wherein a cross-sectional shape of an upper surface of the first light detection device is equal to a cross-sectional shape of an upper surface of the second light detection device.

11. The image sensor of claim 1, further comprising: an electrode pattern configured to electrically connect each of the first light detection device and the second light detection device to the main body,
wherein a shape of the electrode pattern connecting the first light detection device to the main body is different from a shape of the electrode pattern connecting the second light detection device to the main body.

12. The image sensor of claim 1, further comprising: a first electrode, a second electrode, and a third electrode that are spaced apart from each other in the first groove and are configured to electrically connect the first light detection device to the main body.

13. The image sensor of claim 12, wherein
the first electrode is configured to apply a ground signal from the main body to the first light detection device,
the second electrode is configured to apply a driving signal from the main body to the first light detection device, and
the third electrode is configured to apply the electrical signal from the first light detection device to the main body.

14. The image sensor of claim 1, wherein
each of the first light detection device and the second light detection device comprises a light detection layer configured to detect light, and a circuit layer configured to output a voltage corresponding to the detected light, and the main body comprises:
a plurality of analog-to-digital converters respectively corresponding to the circuit layers of the first light detection device and the second light detection device, respectively, and configured to convert the voltages received from the corresponding circuit layers into digital signals; and
an image processor configured to generate the image by using the digital signals output from the plurality of analog-to-digital converters.

15. The image sensor of claim 1, wherein
each of the first light detection device and the second light detection device comprises a light detection layer configured to detect light and a first circuit layer configured to output a floating diffusion signal corresponding to the detected light, and
the main body comprises:
a plurality of second circuit layers respectively corresponding to the first circuit layers of the first light detection device and the second light detection device, respectively, and configured to output voltages corresponding to the floating diffusion signals received from the corresponding first circuit layers;
a plurality of analog-to-digital converters respectively corresponding to the plurality of second circuit layers and configured to convert the voltages received from the corresponding second circuit layers into digital signals; and
an image processor configured to generate the image by using the digital signals output from the plurality of analog-to-digital converters.

16. The image sensor of claim 1, wherein a material included in the first light detection device is absent in the second light detection device.

17. The image sensor of claim 1, wherein each of the first light detection device and the second light detection device comprises any one of a light detection device based on a group IV semiconductor, a light detection device based on a group III-V semiconductor, a light detection device based on a quantum dot, and a light detection device based on a structure smaller than a wavelength of detected light.

18. The image sensor of claim 1, wherein
the first light detection device is configured to detect visible light, and
the second light detection device is configured to detect infrared light or ultraviolet rays.

19. The image sensor of claim 1, wherein
the main body comprises a third light detection device disposed in an upper region of the main body, configured to detect visible light, and output an electrical signal corresponding to light detected by the third light detection device, and
thicknesses of the first groove and the second groove are substantially same as a thickness of the third light detection device.

20. An image sensor comprising:
a main body comprising a plurality of grooves with a plurality of different cross-sectional shapes;
a plurality of semiconductor chips classified into two or more different chip types based on a material and a structure,
wherein among the plurality of semiconductor chips, semiconductor chips of a same chip type have a same cross-sectional shape, and semiconductor chips of different chip types have different cross-sectional shapes, and
wherein each of the plurality of grooves is configured to accommodate only a semiconductor chip with a corresponding cross-sectional shape and a corresponding electrode pattern, among the plurality of semiconductor chips with a plurality of different sectional shapes and a plurality of different electrode patterns.
